(19) United States
(12) Patent Application Publication
(10) Pub. No.: US 2010/0080063 A1
(43) Pub. Date: Apr. 1, 2010

(54) NONVOLATILE SEMICONDUCTOR MEMORY DEVICE

(76) Inventor: Michio Nakagawa, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/504,201

(22) Filed: Jul. 16, 2009

(30) Foreign Application Priority Data
Sep. 26, 2008 (JP) 2008-248664

(51) Int. Cl. G11C 16/04; G11C 5/14

(52) U.S. Cl. 365/185.18; 365/226

(57) ABSTRACT

A nonvolatile semiconductor memory device includes a memory cell group, transfer transistor, and switching circuit. The memory cell group has a plurality of memory cells each including a floating gate and control gate, and the current paths of the plurality of memory cells are connected in series. The transfer transistor transfers a write voltage to at least one memory cell in the memory cell group. The switching circuit applies a voltage to the gate of the transfer transistor. In a write operation, when a first voltage higher than a power supply voltage and lower than the write voltage is applied to the control gate of an unselected memory cell, the switching circuit applies an intermediate voltage higher than the first voltage and equal to or lower than the write voltage to the gate of the transfer transistor.

### CROSS-REFERENCE TO RELATED APPLICATIONS

This application is based upon and claims the benefit of priority from prior Japanese Patent Application No. 2008-248664, filed Sep. 26, 2008, the entire contents of which are incorporated herein by reference.

### BACKGROUND OF THE INVENTION

1. Field of the Invention

The present invention relates to a nonvolatile semiconductor memory device, e.g., a NAND flash memory.

2. Description of the Related Art

Recently, demands for nonvolatile memories are increasing as the storage capacity increases. An example of a nonvolatile memory is a NAND flash memory (see, e.g., Jpn. Pat. Appln. KOKAI Publication No. 2004-14043).

In the NAND flash memory, a high voltage (write voltage or erase voltage) must be applied to a memory cell when performing a write operation or erase operation. In addition, a higher voltage must be applied to a memory cell as the number of logical levels of a memory cell in the NAND flash memory increases.

### BRIEF SUMMARY OF THE INVENTION

According to a first aspect of the present invention, there is provided a nonvolatile semiconductor memory device comprising: a memory cell group having a plurality of memory cells each including a floating gate and a control gate, the plurality of memory cells having current paths connected in series; a first transfer transistor which transfers a write voltage to at least one memory cell in the memory cell group; and a switching circuit which applies a voltage to a gate of the first transfer transistor. In a write operation, when a first voltage higher than a power supply voltage and lower than the write voltage is applied to the control gate of an unselected memory cell, the switching circuit applies an intermediate voltage higher than the first voltage and not more than the write voltage to the gate of the first transfer transistor.

According to a second aspect of the present invention, there is provided a nonvolatile semiconductor memory device comprising: a memory cell group having a plurality of memory cells each including a floating gate and a control gate, the plurality of memory cells having current paths connected in series; a first transfer transistor connected to the control gate of at least one memory cell in the memory cell group; and a switching circuit which applies a voltage to a gate of the first transfer transistor. In a write operation, when a first voltage higher than a power supply voltage and lower than a write voltage is applied to the control gate of an unselected memory cell, the switching circuit applies an intermediate voltage higher than the first voltage and not more than the write voltage to the gate of the first transfer transistor.

According to a third aspect of the present invention, there is provided a nonvolatile semiconductor memory device comprising: a memory cell group having a plurality of memory cells each including a floating gate and a control gate, the plurality of memory cells having current paths connected in series; a first transfer transistor which transfers a write voltage to at least one memory cell in the memory cell group; and a switching circuit which applies a voltage to a gate of the first transfer transistor. In a write operation, immediately before a first voltage higher than a power supply voltage and lower than the write voltage is applied to the control gate of an unselected memory cell, the switching circuit applies an intermediate voltage higher than the first voltage and not more than the write voltage to the gate of the first transfer transistor.

### BRIEF DESCRIPTION OF THE SEVERAL VIEWS OF THE DRAWING

FIGS. 1A, 1B, and 1C are views showing the arrangement of a block in a NAND flash memory of the first embodiment of the present invention;

FIG. 2 is a view showing the threshold voltage distributions of memory cells when the NAND flash memory is multileveled;

FIG. 3 is a view showing the threshold voltage distributions of memory cells when the NAND flash memory is multileveled;

FIG. 4 is a graph showing the rise in threshold voltage caused by high-voltage stress applied to a transfer transistor;

FIG. 5 is a graph showing the change in threshold voltage as a function of the application time during which a voltage is applied to the transfer transistor in a write operation;

FIG. 6 is a timing chart showing voltage waveforms to be applied to the transfer transistor as a comparative example;

FIG. 7A is a timing chart showing voltage waveforms to be applied to the transfer transistor and switching signals in the first embodiment of the present invention;

FIG. 7B is a view showing the configuration of control switching circuits according to the first embodiment;

FIGS. 8A and 8B are views showing detailed circuit examples of the control switching circuit shown in FIG. 7B according to the first embodiment;

FIGS. 9A and 9B are views showing detailed circuit examples of the control switching circuit shown in FIG. 7B according to the first embodiment;

FIG. 10 is a circuit diagram of a boosting circuit for generating a voltage “VPGM+Vth” in the first embodiment;

FIG. 11 is a circuit diagram of a boosting circuit for generating a voltage “VPASS+Vth” in the first embodiment;

FIG. 12 is a circuit diagram for generating a threshold voltage Vth in the first embodiment;

FIG. 13A is a timing chart showing voltage waveforms to be applied to a transfer transistor and switching signals in the second embodiment of the present invention;

FIG. 13B is a view showing the configuration of control switching circuits according to the second embodiment;

FIG. 14 is a timing chart showing voltages to be applied to the transfer transistor when performing a read operation and write operation;

FIG. 15 is a circuit diagram of a boosting circuit for generating a voltage “VREAD+Vth” in the second embodiment;

FIG. 16A is a circuit diagram showing the arrangements of transfer transistors and a NAND string in the third embodiment of the present invention; and

FIG. 16B is a view showing voltage waveforms to be applied to the transfer transistor in the third embodiment.

### DETAILED DESCRIPTION OF THE INVENTION

Nonvolatile semiconductor memory devices of embodiments of the present invention will be explained below with reference to the accompanying drawing. In each embodiment, a NAND flash memory will be taken as an example of the nonvolatile semiconductor memory device. In the following explanation, the same reference numerals denote the same parts throughout the drawing.

### First Embodiment

First, a NAND flash memory of the first embodiment of the present invention will be explained below.

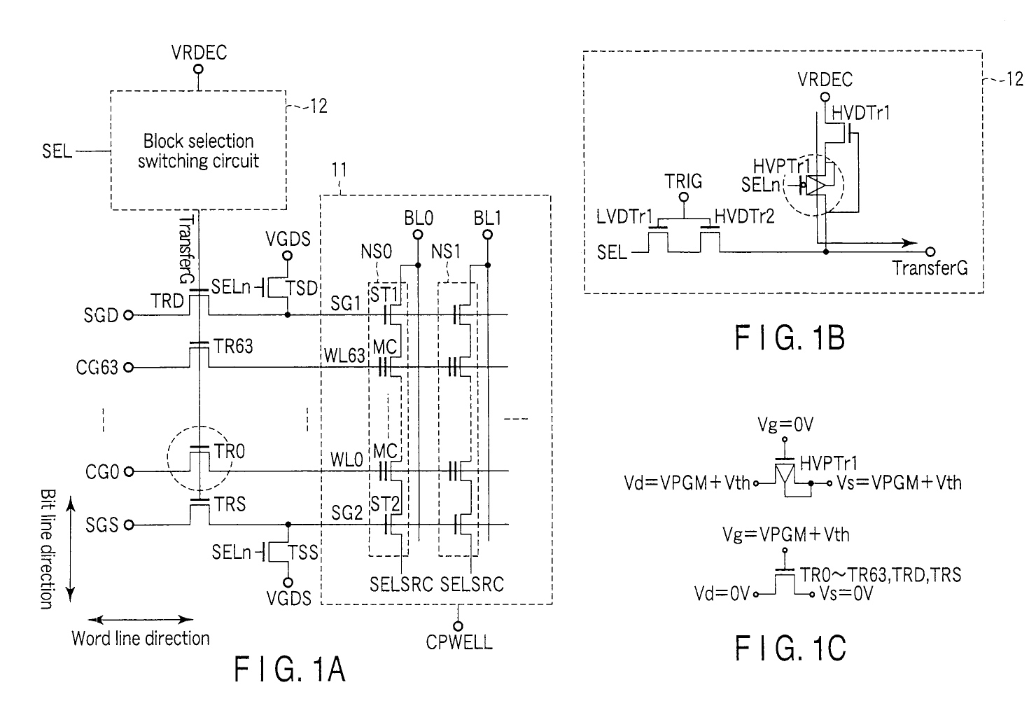

FIG. 1A is a circuit diagram showing the arrangement of a block in the NAND flash memory of the first embodiment.

As shown in FIG. 1A, the block of the NAND flash memory includes a cell array unit 11, a block selection switching circuit 12, transfer transistors TR0 to TR63, TRS, and TRD, and selection transistors TSS and TSD.

The cell array unit 11 has a plurality of NAND strings NS0, NS1, . . . arranged in the word line direction. Each NAND string has a plurality of memory cells MC and selection gate transistors ST1 and ST2. The current paths of the plurality of memory cells MC are connected in series to form a memory cell group. That is, the memory cell group is formed by connecting the plurality of memory cells MC in series so that these memory cells share the sources and drains. The selection gate transistor ST1 is connected to the memory cell MC at one end of the memory cell group. The selection gate transistor ST2 is connected to the memory cell MC at the other end of the memory cell group. Bit lines BL0, BL1, . . . are connected to the plurality of selection gate transistors ST1. A source line SELSRC is connected to the plurality of selection gate transistors ST2.

The block selection switching circuit 12 receives a voltage VRDEC from a power supply circuit, and also receives a selection signal SEL. The block selection switching circuit 12 selects a block in accordance with the selection signal SEL, and outputs the voltage VRDEC. The voltage VRDEC (TransferG) output from the block selection switching circuit 12 is applied to the gates of the transfer transistors TR0 to TR63, TRS, and TRD.

Control gate lines CG0 to CG63 are respectively connected to word lines WL0 to WL63 via the current paths of the transfer transistors TR0 to TR63. The word lines WL0 to WL63 are connected to the gates of a plurality of memory cells MC arranged in the word line direction. Selection gate lines SGD and SGS are respectively connected to selection gate lines SG1 and SG2 via the current paths of the transfer transistors TRD and TRS. The selection gate lines SG1 and SG2 are respectively connected to the gates of the plurality of selection gate transistors ST1 and ST2 arranged in the word line direction. In addition, the transistor TSD is connected to the selection gate line SG1, and the transistor TSS is connected to the selection gate line SG2.

Note that the arrangement shown in FIG. 1A indicates one block in the NAND flash memory, and the NAND flash memory is formed by arranging a plurality of such blocks.

FIG. 1B is a circuit diagram showing details of the block selection switching circuit 12 in the block. As shown in FIG. 1B, the block selection switching circuit 12 has transistors HVDTr1, HVDTr2, HVPTr1, and LVDTr1. The transistors HVDTr1 and HVDTr2 are depletion type, high-voltage, n-channel MOS field-effect transistors (to be referred to as nMOS transistors hereinafter). The transistor HVPTr1 is a high-voltage, p-channel MOS field-effect transistor (to be referred to as a pMOS transistor hereinafter). The transistor LVDTr1 is a depletion type, low-voltage nMOS transistor.

The voltage VRDEC is applied to the drain of the transistor HVDTr1. The source of the transistor HVDTr1 is connected to the source of the transistor HVPTr1. The drain of the transistor HVPTr1 is connected to the gate of the transistor HVDTr1.

The signal SEL is supplied to the drain of the transistor LVDTr1. The source of the transistor LVDTr1 is connected to the drain of the transistor HVDTr2. The source of the transistor HVDTr2 is connected to the drain of the transistor HVPTr1. A selection signal SELn is input to the gate of the transistor HVPTr1. A signal TRIG is input to the gates of the transistors LVDTr1 and HVDTr2. The voltage VRDEC (TransferG) is output from the drain of the transistor HVPTr1.

High-voltage stress to be applied to the transfer transistors in the block shown in FIGS. 1A and 1B will be explained below.

FIG. 1C is a view showing voltages to be applied to the transfer transistors HVPTr1, TR0 to TR63, TRD, and TRS in the block.

When performing a write operation as shown in FIG. 1C, high-voltage stress “write voltage VPGM+threshold voltage Vth” is applied to gate insulating films (e.g., silicon oxide films) of the transistors HVPTr1, TR0 to TR63, TRD, and TRS.

The influence of this high-voltage stress on the transistor characteristics will now be explained. As an example, a multileveled memory cell of the NAND flash memory will be explained below.

First, the reason why the write voltage rises when a memory cell of the NAND flash memory is multileveled will be explained.

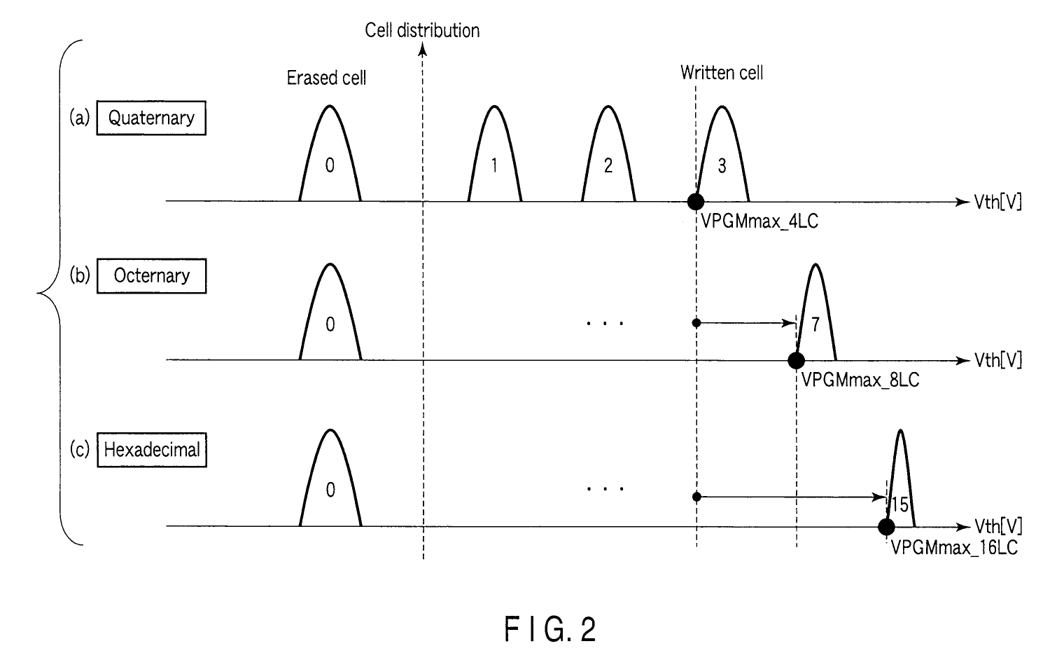

FIG. 2 is a view showing the threshold voltage distributions of memory cells when the NAND flash memory is multileveled.

When the memory is quaternary, for example, four cell threshold distributions (to be referred to as cell distributions hereinafter) exist as shown in a row (a) of FIG. 2. In this state, the threshold voltage of a memory cell in cell distribution “3” on a highest voltage side determines a maximum voltage (to be referred to as a maximum write voltage hereinafter) VPGMmax_{—}4LC of the write voltage in a write operation. When the memory is octernary, eight cell distributions exist as shown in a row (b) of FIG. 2. In this state, the threshold voltage of a memory cell in cell distribution “7” on a highest voltage side determines a maximum write voltage VPGMmax_{—}8LC in a write operation. When the memory is hexadecimal, 16 cell distributions exist as shown in a row (c) of FIG. 2. In this state, the threshold voltage of a memory cell in cell distribution “15” on a highest voltage side determines a maximum write voltage VPGMmax_{—}16LC in a write operation.

As can be understood from the above description, the maximum write voltage must be raised as the threshold voltage of a memory cell rises. As the number of logical levels increases from, e.g., 4 to 8 or 16, therefore, the maximum write voltage in a write operation rises.

Also, as the memory cell is multileveled, the application time of the write voltage prolongs. The reason why the application time prolongs will be explained below with reference to the accompanying drawing.

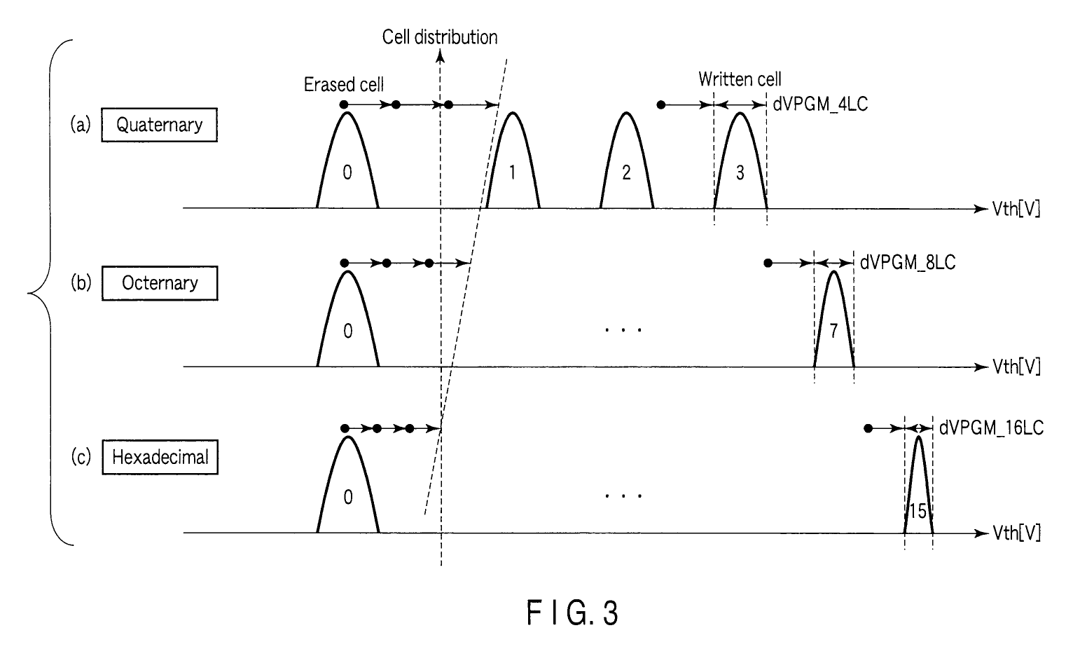

FIG. 3 is a view showing the threshold voltage distributions of memory cells when the NAND flash memory is multileveled, and indicates that the application time of the write voltage prolongs.

As memory cells are multileveled, the number of cell distributions increases. Therefore, the width of the cell threshold distribution (the cell distribution width) when processing octernary data must be made smaller than that when processing quaternary data. Furthermore, the cell distribution width when processing hexadecimal data must be made smaller than that when processing octernary data. To decrease the cell distribution width, a step-up width dVPGM of the write voltage must be decreased. When the step-up width dVPGM of the write voltage decreases, the number of times of application of a program pulse required to write to the voltage level of a cell distribution on a highest voltage side increases. Accordingly, when the number of times of application of the program pulse increases, the application time of the write voltage prolongs.

As described above, as the application voltage and application time of the write voltage in a write operation increase, the high-voltage stress applied to the transfer transistors deteriorates the transistor characteristics. Examples of the deterioration of the transistor characteristics are the rise in threshold voltage, the reduction in drain (source) current when the transistor is ON, and the increase in leakage current when the transistor is OFF.

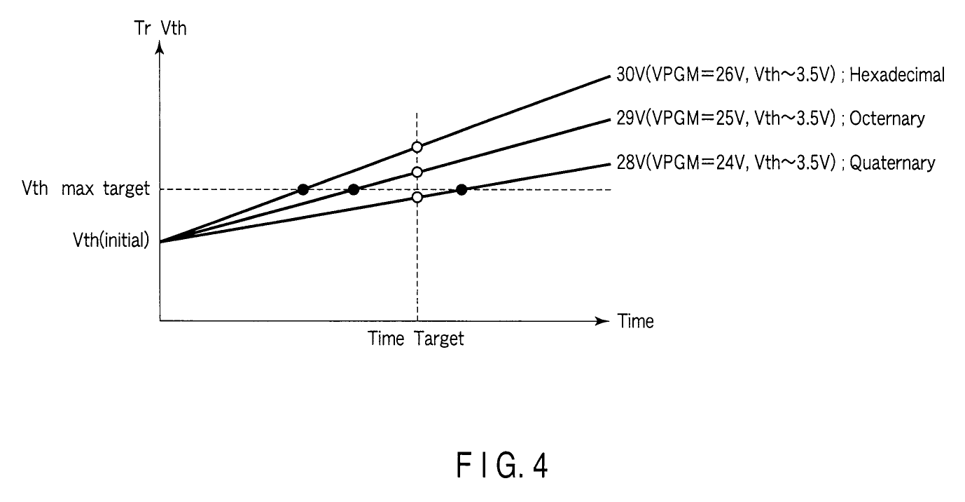

FIG. 4 is a graph showing the rise in threshold voltage caused by the high-voltage stress applied to the transfer transistor.

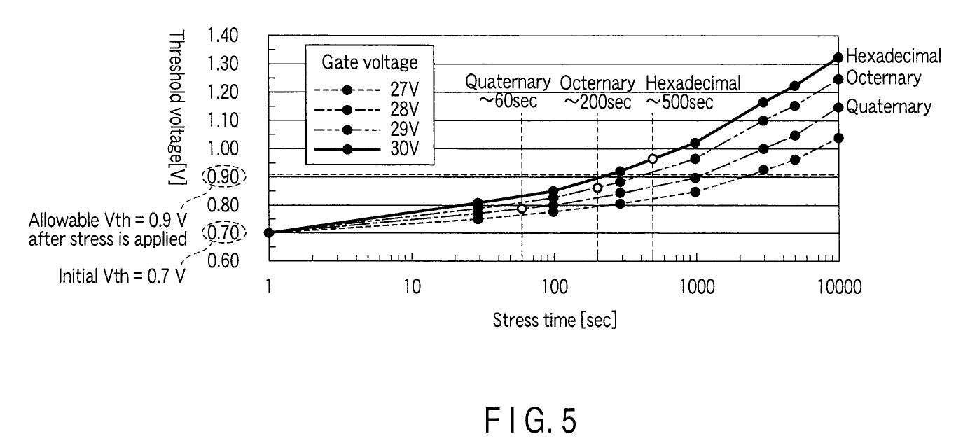

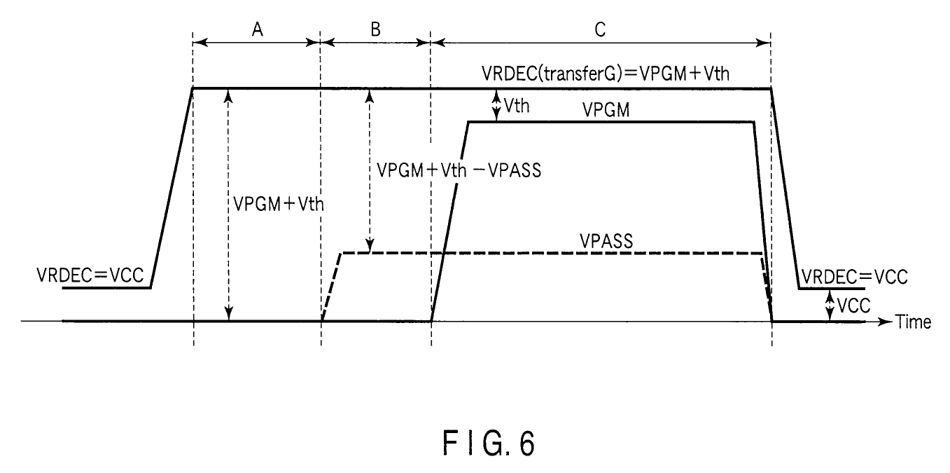

When performing a write operation, a high write voltage is applied to the gate insulating film of the transfer transistor. FIG. 4 shows the rise in threshold voltage of the transfer transistor in this case. That is, FIG. 4 represents the transition of the threshold voltage when the write voltage is 28 V (quaternary), 29 V (octernary), and 30 V (hexadecimal), by plotting the application time on the abscissa and the threshold voltage on the ordinate. FIG. 4 reveals that as the application voltage of the write voltage to be applied to the transfer transistor rises and the application time prolongs, deterioration of the transistor characteristics is accelerated. The rise in threshold voltage of the transfer transistor caused by the high-voltage stress will be described in detail below with reference to FIGS. 5 and 6.

FIG. 5 is a graph of examples of real characteristics, showing the change in threshold voltage caused by the application time of a voltage to be applied to the transfer transistor when performing a write operation. FIG. 6 is a timing chart showing voltage waveforms to be applied to the transfer transistors TR0 to TR63, TRD, and TRS in the present circuit system. Note that the voltage, stress time, allowable voltage target, and the like shown in FIG. 5 are merely examples, and these values change in accordance with conditions such as the specifications of the NAND flash and the characteristics of the transistors.

The voltage waveforms shown in FIG. 6 are as follows. The voltage VRDEC indicates a gate voltage to be applied to the gates of the transfer transistors TR0 to TR63. Voltages VPASS and VPGM indicate voltages to be applied to the drain-to-source channels of the transfer transistors TR0 to TR63, TRD, and TRS. When performing a write operation, the voltage VPASS is applied to a transfer transistor of a word line connected to an unselected memory cell, and the voltage VPGM is applied to a transfer transistor of a word line connected to a selected memory cell.

As shown in FIG. 6, in period A before the voltage VPASS is applied, the voltage VRDEC is higher by the threshold voltage Vth of the transfer transistor than the voltage VPGM. Likewise, in period B during which the voltage VPASS is applied, the voltage VRDEC is higher by the threshold voltage Vth than the voltage VPGM. In period C during which the voltage VPGM is applied, the voltage VRDEC is still higher by the threshold voltage Vth than the voltage VPGM. Therefore, the voltage stress applied to the transfer transistor is maximum in period A, and large in period B as well.

Accordingly, as the number of logical levels of memory cells increases to 4, 8, and 16, both the stress voltage to be applied to the transfer transistor and the stress time increase. For example, the stress voltage and allowable stress time are respectively 28 V and 60 sec for a quaternary memory cell, 29 V and 200 sec for an octernary memory cell, and 30 V and 500 sec for a hexadecimal memory cell. Therefore, if the voltage as shown in FIG. 6 is applied to the transfer transistor by the present circuit system, the rise in threshold voltage Vth exceeds 0.9 V, i.e., falls outside the range of specifications for a hexadecimal memory cell. For an octernary memory cell, the rise in threshold voltage Vth does not reach 0.9 V, but the margin is small.

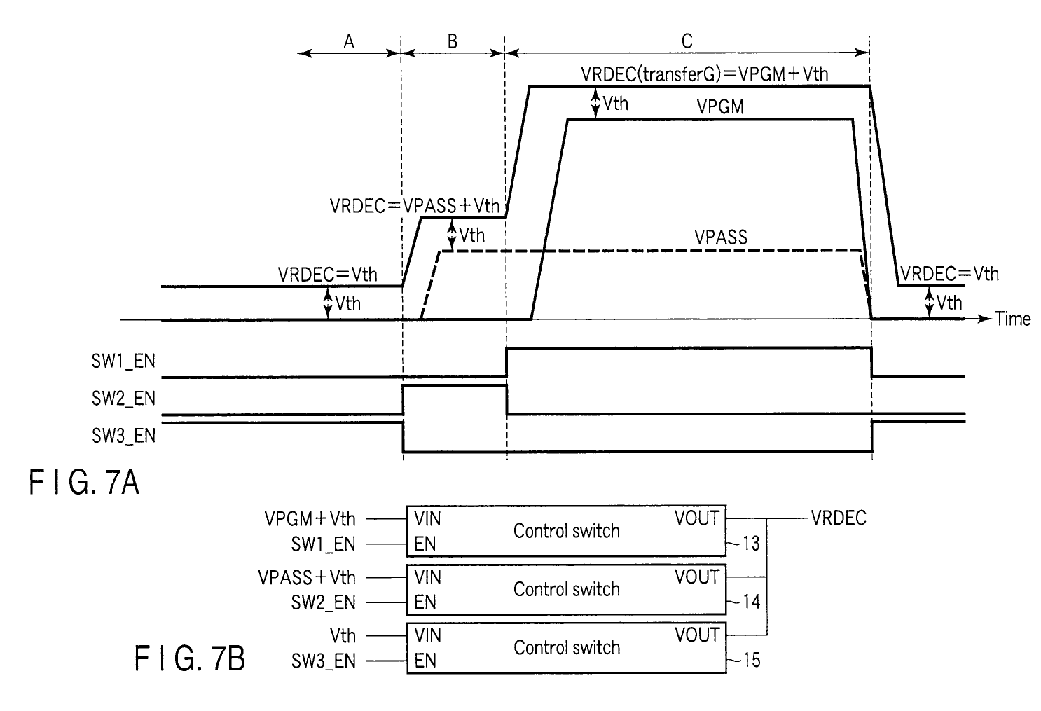

As a measure to solve this problem, therefore, this embodiment uses voltage waveforms as shown in a row (a) of FIG. 7A, which are obtained by reducing the stress voltage to be applied to the gate insulating film and the stress time compared to the voltage waveforms shown in FIG. 6.

The voltage waveforms shown in the row (a) of FIG. 7A are as follows. The voltage VRDEC indicates the gate voltage to be applied to the gates of the transfer transistors TR0 to TR63. The voltages VPASS and VPGM indicate voltages to be applied to the drain-to-source channels of the transfer transistors TR0 to TR63, TRD, and TRS. When performing a write operation, the voltage VPASS is applied to a transfer transistor of a word line connected to an unselected memory cell, and the voltage VPGM is applied to a transfer transistor of a word line connected to a selected memory cell.

As shown in the row (a) of FIG. 7, in period A before the voltage VPASS is applied, the voltage VRDEC is higher by the threshold voltage Vth of the transfer transistor than a reference voltage (e.g., the ground potential). In period B during which the voltage VPASS is applied, the voltage VRDEC is higher by the threshold voltage Vth than the voltage VPASS. In period C during which the voltage VPGM is applied, the voltage VRDEC is higher by the threshold voltage Vth than the voltage VPGM.

As described above, the voltage VRDEC to be applied to the gate of the transfer transistor is controlled so as to be applied as a minimal necessary voltage for only the shortest time. This makes it possible to minimize the stress voltage to be applied to the transfer transistor and the stress time.

A row (b) of FIG. 7A is a timing chart of switching signals for controlling the voltage VRDEC. FIG. 7B is a view showing the arrangement of control switching circuits for controlling the output voltage of the voltage VRDEC.

A control switching circuit 13 receives a voltage “VPGM+Vth” at an input terminal VIN, and a switching signal SW1_EN at an input terminal EN. The control switching circuit 13 outputs the voltage VRDEC from an output terminal VOUT. A control switching circuit 14 receives a voltage “VPASS+Vth” at an input terminal VIN, and a switching signal SW2_EN at an input terminal EN. The control switching circuit 14 outputs the voltage VRDEC from an output terminal VOUT. A control switching circuit 15 receives the voltage Vth at an input terminal VIN, and a switching signal SW3_EN at an input terminal EN. The control switching circuit 15 outputs the voltage VRDEC from an output terminal VOUT.

The control switching circuits as described above operate as follows upon receiving the switching signals as shown in the row (b) of FIG. 7A. First, in period A, the switching signals SW1_EN and SW2_EN are at “L”, and the switching signal SW3_EN is at “H”, so the control switching circuit 15 outputs the voltage Vth from the output terminal VOUT. Then, in period B, the switching signal SW1_EN is at “L”, the switching signal SW2_EN is at “H”, and the switching signal SW3_EN is at “L”, so the control switching circuit 14 outputs the voltage “VPASS+Vth” from the output terminal VOUT. Furthermore, in period C, the switching signal SW1_EN is at “H”, and the switching signals SW2_EN and SW3_EN are at “L”, so the control switching circuit 13 outputs the voltage “VPGM+Vth” from the output terminal VOUT. As a consequence, the control switching circuits output the voltage VRDEC as shown in the row (a) of FIG. 7A.

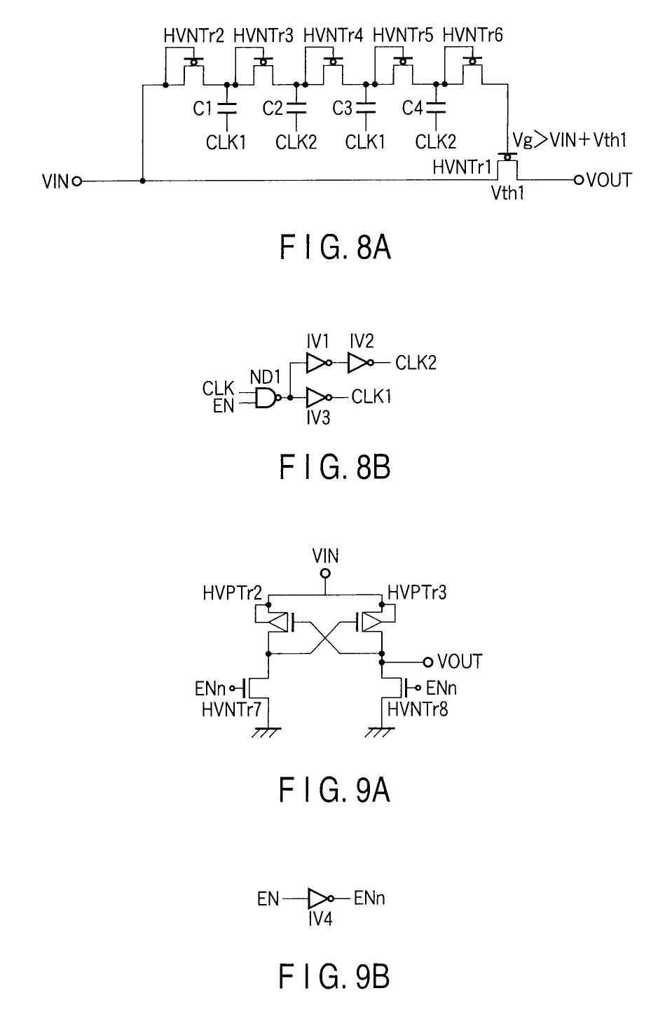

FIGS. 8A, 8B, 9A, and 9B are views showing detailed circuit examples of the control switching circuits shown in FIG. 7B.

FIGS. 8A and 8B illustrate pump type circuits. The circuits shown in FIGS. 8A and 8B include high-voltage nMOS transistors HVNTr1 to HVNTr6, capacitors C1 to C4, a NAND circuit ND1, and inverters IV1 to IV3. Letting Vth1 be the threshold voltage of the nMOS transistor HVNTr1, a gate voltage Vg of the nMOS transistor HVNTr1 is “voltage input to VIN+Vth1”, and the voltage VRDEC is output from an output terminal VOUT. The circuit shown in FIG. 8B generates clock signals CLK1 and CLK2 to be supplied to the capacitors C1 to C4.

FIGS. 9A and 9B illustrate level shifter type circuits. The circuit shown in FIG. 9A includes high-voltage pMOS transistors HVPTr2 and HVPTr3, and high-voltage nMOS transistors HVNTr7 and HVNTr8. The circuit shown in FIG. 9B inverts a signal input to an input terminal EN, thereby generating a signal to be input to an input terminal ENn. The voltage VRDEC can be output from an output terminal VOUT even by using the circuits as shown in FIGS. 9A and 9B.

Next, boosting circuits for generating the voltages “VPGM+Vth”, “VPASS+Vth”, and Vth to be applied as the voltage VRDEC will be explained.

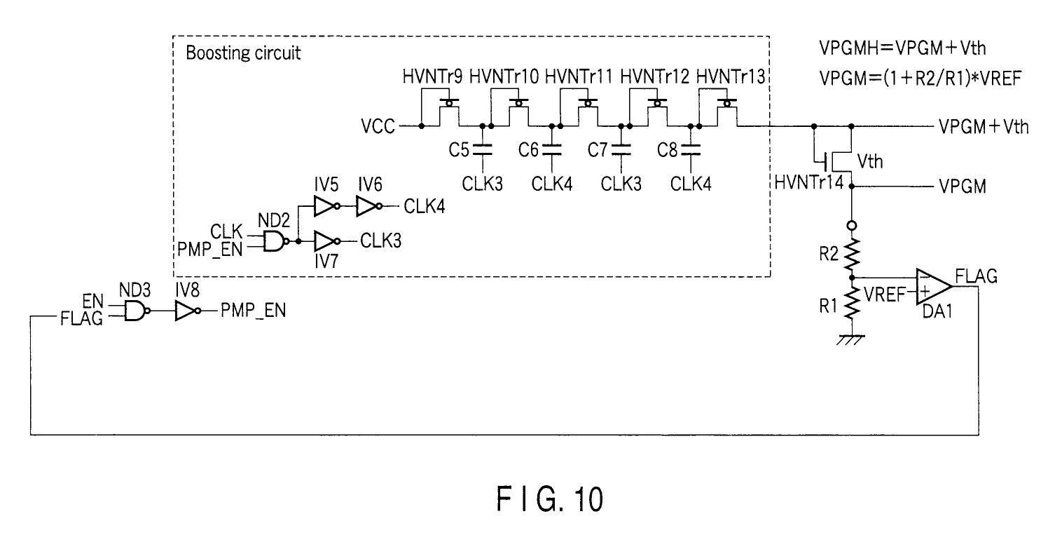

FIG. 10 is a circuit diagram of a boosting circuit for generating the voltage “VPGM+Vth”. The boosting circuit shown in FIG. 10 includes high-voltage nMOS transistors HVNTr9 to HVNTr14, capacitors C5 to C8, resistors R1 and R2, a differential amplifier DA1, NAND circuits ND2 and ND3, and inverters IV5 to IV8.

A power supply voltage VCC is applied to the nMOS transistor HVNTr9. The differential amplifier DA1 receives a voltage between the resistors R1 and R2 at the negative input terminal, and a reference voltage VREF at the positive input terminal. The NAND circuit ND3 receives a signal FLAG output from the output terminal of the differential amplifier DA1 at the first input terminal, and a signal EN at the second input terminal. The NAND circuit ND2 receives a signal PMP_EN output from the inverter IV8 at the first input terminal, and a clock signal CLK at the second input terminal. As shown in FIG. 10, clock signals CLK3 and CLK4 respectively output from the inverters IV7 and IV6 are input to the capacitors C5 to C8. The boosting circuit having this arrangement shown in FIG. 10 generates the voltage “VPGM+Vth”.

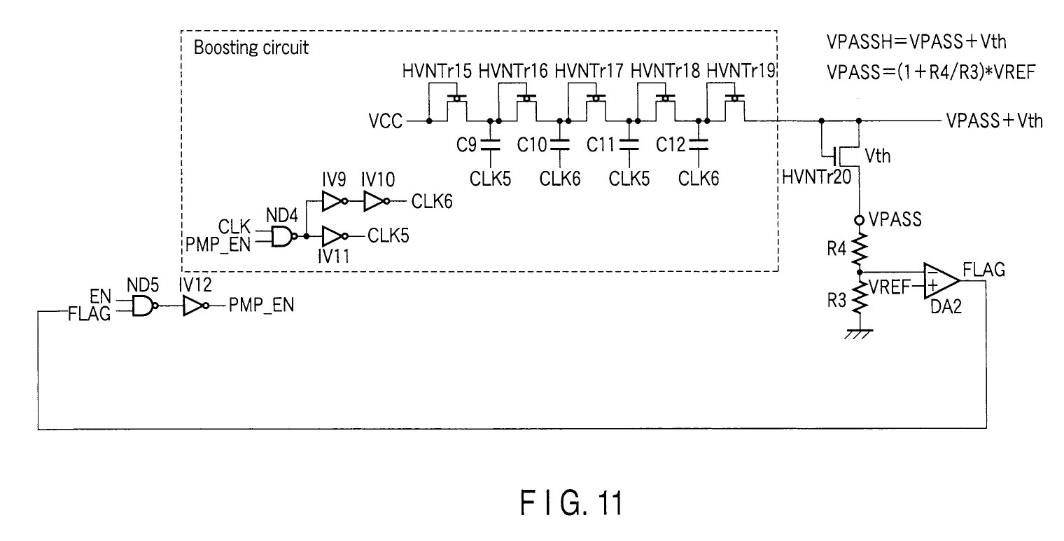

FIG. 11 is a circuit diagram of a boosting circuit for generating the voltage “VPASS+Vth”. The boosting circuit shown in FIG. 11 includes high-voltage nMOS transistors HVNTr15 to HVNTr20, capacitors C9 to C12, resistors R3 and R4, a differential amplifier DA2, NAND circuits ND4 and ND5, and inverters IV9 to IV12.

The power supply voltage VCC is applied to the nMOS transistor HVNTr15. The differential amplifier DA2 receives a voltage between the resistors R3 and R4 at the negative input terminal, and the reference voltage VREF at the positive input terminal. The NAND circuit ND5 receives the signal FLAG output from the output terminal of the differential amplifier DA2 at the first input terminal, and the signal EN at the second input terminal. The NAND circuit ND4 receives the signal PMP_EN output from the inverter IV12 at the first input terminal, and the clock signal CLK at the second input terminal. As shown in FIG. 11, clock signals CLK5 and CLK6 respectively output from the inverters IV11 and IV10 are input to the capacitors C9 to C12. The boosting circuit having this arrangement shown in FIG. 11 generates the voltage “VPASS+Vth”.

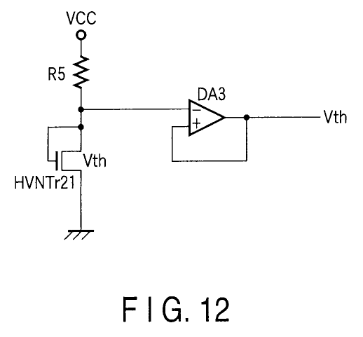

FIG. 12 is a diagram for generating the threshold voltage Vth. The power supply voltage VCC is applied to one terminal of a resistor R5. The other terminal of the resistor R5 is connected to a reference voltage terminal (e.g., the ground potential) via a high-voltage nMOS transistor HVNTr21. A node between the resistor R5 and nMOS transistor HVNTr21 is connected to the negative input terminal of a differential amplifier DA3, and the output terminal of the differential amplifier DA3 is connected to its positive input terminal. The differential amplifier DA3 outputs the threshold voltage Vth from the output terminal.

When performing a write operation in the first embodiment as explained above, the voltage VRDEC (=VPASS+Vth) is applied to the gate of the transfer transistor in period B during which the voltage VPASS is applied to an unselected word line and the voltage VPGM is not applied to a selected word line (the selected word line is at 0 V), and the voltage VRDEC (=Vth) is applied to the gate of the transfer transistor in period A immediately before the voltage VPASS is applied to the unselected word line. In other words, when raising the voltage VRDEC from the voltage Vth to the voltage “VPGM+Vth” in the first embodiment, the voltage VRDEC is first raised from the voltage Vth to the voltage “VPASS+Vth” (an intermediate voltage) and maintained at the voltage “VPASS+Vth” for a predetermined time, and then raised from the voltage “VPASS+Vth” to the voltage “VPGM+Vth”. This makes it possible to apply a minimal necessary voltage to the transfer transistor for only a minimal necessary time in a write operation, and reduce the voltage stress to be applied to the gate insulating film of the transfer transistor.

Note that when using the voltage waveforms as shown in the row (a) of FIG. 7A described previously, the fluctuation in threshold value of the transfer transistor caused by the voltage stress can be reduced. Therefore, deterioration of the transfer transistor can be reduced not only for hexadecimal or octernary data but also for quaternary data. This makes it possible to apply this embodiment not only to a hexadecimal or octernary NAND flash memory but also to a quaternary NAND flash memory.

Note that the control switching circuits shown in FIGS. 8A, 8B, 9A, and 9B are merely examples. Accordingly, any type of circuit is applicable to this embodiment as long as the circuit includes a circuit capable of high-voltage transfer and a switch and enable logic circuit for controlling the timing of the high-voltage transfer circuit.

Note also that the boosting circuits (power supply circuits) shown in FIGS. 10 to 12 are merely examples, and any type of circuit capable of generating a predetermined voltage is applicable to this embodiment.

### Second Embodiment

A NAND flash memory of the second embodiment of the present invention will be explained below. In the first embodiment, a voltage VRDEC is made higher by a threshold voltage Vth than a voltage VPASS in period B during which the voltage VPASS is applied. In the second embodiment, the voltage VRDEC is made higher by the threshold voltage Vth than a voltage VREAD in period B. The voltage VREAD is applied to a word line connected to an unselected memory cell in a read operation. The same reference numerals as in the arrangement of the first embodiment denote the same parts, and a repetitive explanation will be omitted.

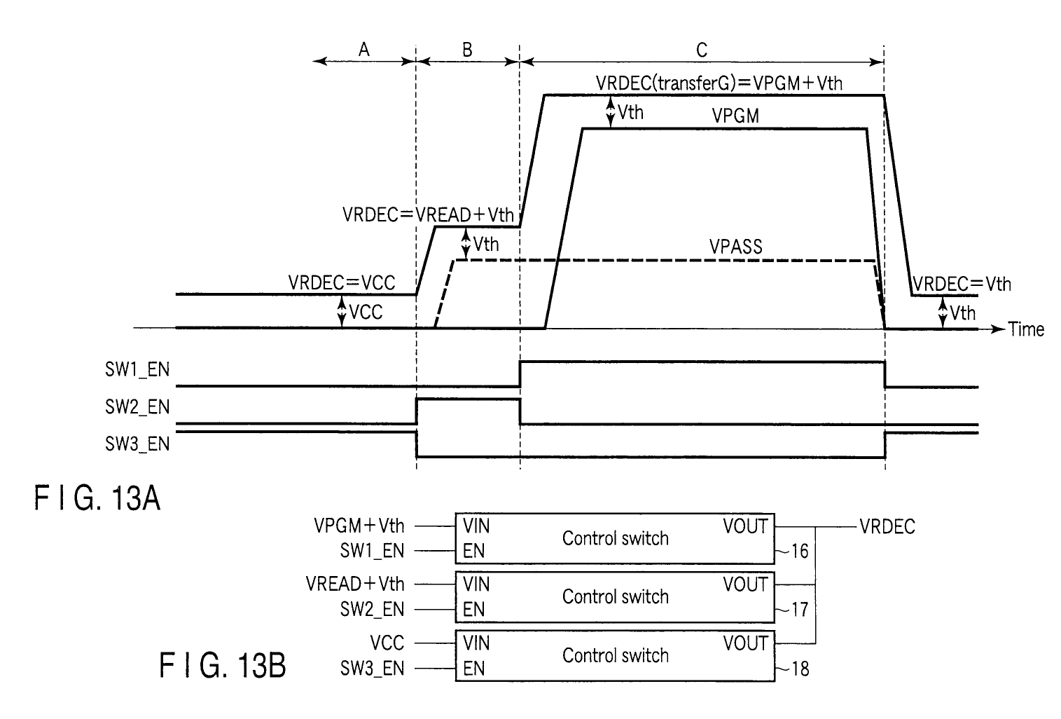

A row (a) of FIG. 13A is a view showing voltage waveforms to be applied to transfer transistors TR0 to TR63, TRD, and TRS in the second embodiment of the present invention.

As shown in the row (a) of FIG. 13A, in period A before the voltage VPASS is applied, the voltage VRDEC is higher by a power supply voltage VCC than a reference voltage (e.g., the ground potential). In period B during which the voltage VPASS is applied, the voltage VRDEC is higher by the threshold voltage Vth of the transfer transistor than the voltage VREAD. In period C during which a voltage VPGM is applied, the voltage VRDEC is higher by the threshold voltage Vth than the voltage VPGM.

By thus controlling the voltage VRDEC to be applied to the gate of the transfer transistor so as to apply a minimal necessary voltage for only a minimal time, it is possible to reduce the stress voltage to be applied to the transfer transistor and the stress time.

A row (b) of FIG. 13A is a timing chart of switching signals for controlling the voltage VRDEC. FIG. 13B is a view showing the arrangement of control switching circuits for controlling the output voltage of the voltage VRDEC.

A control switching circuit 16 receives a voltage “VPGM+Vth” at an input terminal VIN, and a switching signal SW1_EN at an input terminal EN. The control switching circuit 16 outputs the voltage VRDEC from an output terminal VOUT. A control switching circuit 17 receives a voltage “VREAD+Vth” at an input terminal VIN, and a switching signal SW2_EN at an input terminal EN. The control switching circuit 17 outputs the voltage VRDEC from an output terminal VOUT. A control switching circuit 18 receives the voltage VCC at an input terminal VIN, and a switching signal SW3_EN at an input terminal EN. The control switching circuit 18 outputs the voltage VRDEC from an output terminal VOUT.

The control switching circuits as described above operate as follows upon receiving the switching signals as shown in the row (b) of FIG. 13A. First, in period A, the switching signals SW1_EN and SW2_EN are at “L”, and the switching signal SW3_EN is at “H”, so the control switching circuit 18 outputs the voltage VCC from the output terminal VOUT. Then, in period B, the switching signal SW1_EN is at “L”, the switching signal SW2_EN is at “H”, and the switching signal SW3_EN is at “L”, so the control switching circuit 17 outputs the voltage “VREAD+Vth” from the output terminal VOUT. Furthermore, in period C, the switching signal SW1_EN is at “H”, and the switching signals SW2_EN and SW3_EN are at “L”, so the control switching circuit 16 outputs the voltage “VPGM+Vth” from the output terminal VOUT. As a consequence, the control switching circuits output the voltage VRDEC as shown in the row (a) of FIG. 13A.

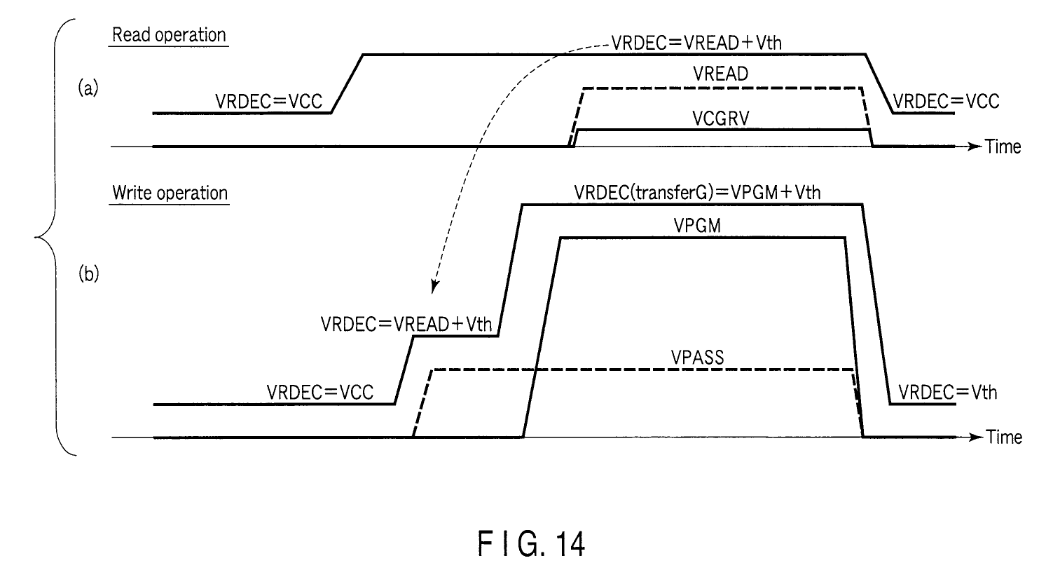

Rows (a) and (b) of FIG. 14 respectively illustrate voltages to be applied to the transfer transistor during a read operation and write operation.

The voltage VREAD to be applied to an unselected word line in the read operation is almost equal to the voltage VPASS to be applied to an unselected word line in the write operation. Therefore, the voltage VREAD is used.

When performing the read operation, the voltage VRDEC is raised to the voltage “VREAD+Vth” in order to transfer the voltage VREAD to a memory cell. Accordingly, in period B during which the voltage VPASS is applied in the write operation, the voltage VRDEC is raised to the voltage “VREAD+Vth” by using the voltage “VREAD+Vth” generated in the read operation. As described above, the voltage “VREAD+Vth” used in the read operation is also used in the write operation of this embodiment. This facilitates the write operation because it is unnecessary to generate any new power supply.

A boosting circuit for generating the voltage “VREAD+Vth” generated in the read operation, i.e., the voltage “VREAD+Vth” to be applied as the voltage VRDEC will be explained below.

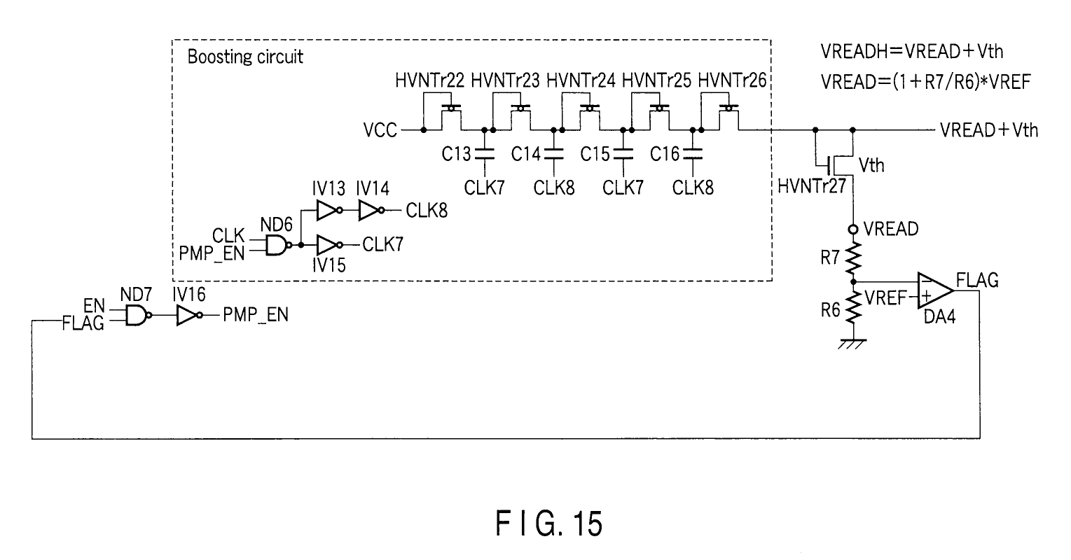

FIG. 15 is a circuit diagram of the boosting circuit for generating the voltage “VREAD+Vth”. The boosting circuit shown in FIG. 15 includes high-voltage nMOS transistors HVNTr22 to HVNTr27, capacitors C13 to C16, resistors R6 and R7, a differential amplifier DA4, NAND circuits ND6 and ND7, and inverters IV13 to IV16.

The power supply voltage VCC is applied to the nMOS transistor HVNTr22. The differential amplifier DA4 receives a voltage between the resistors R6 and R7 at the negative input terminal, and a reference voltage VREF at the positive input terminal. The NAND circuit ND7 receives a signal FLAG output from the output terminal of the differential amplifier DA4 at the first input terminal, and a signal EN at the second input terminal. The NAND circuit ND6 receives a signal PMP_EN output from the inverter IV16 at the first input terminal, and a clock signal CLK at the second input terminal. As shown in FIG. 15, clock signals CLK7 and CLK8 respectively output from the inverters IV15 and IV14 are input to the capacitors C13 to C16. The boosting circuit having this arrangement shown in FIG. 15 generates the voltage “VREAD+Vth”.

When performing a write operation in the second embodiment as explained above, the voltage VRDEC (=VREAD+Vth) is applied to the gate of the transfer transistor in period B during which the voltage VPASS is applied to an unselected word line and the voltage VPGM is not applied to a selected word line (the selected word line is at 0 V), and the voltage VRDEC (=VCC) is applied to the gate of the transfer transistor in period A immediately before the voltage VPASS is applied to the unselected word line. In other words, when raising the voltage VRDEC from the voltage VCC to the voltage “VPGM+Vth” in the second embodiment, the voltage VRDEC is first raised from the voltage VCC to the voltage “VREAD+Vth” (an intermediate voltage) and maintained at the voltage “VREAD+Vth” for a predetermined time, and then raised from the voltage “VREAD+Vth” to the voltage “VPGM+Vth”. This makes it possible to apply a minimal necessary voltage to the transfer transistor for only a minimal necessary time in a write operation, and reduce the voltage stress to be applied to the gate insulating film of the transfer transistor. The rest of the arrangements and effects are the same as those of the first embodiment.

Note that the boosting circuit shown in FIG. 15 is merely an example, and any type of circuit capable of generating a desired voltage is applicable to this embodiment.

### Third Embodiment

A NAND flash memory of the third embodiment of the present invention will be explained below. In the first and second embodiments, when raising a voltage VRDEC to a voltage “VPGM+Vth”, the voltage VRDEC is first raised to an intermediate voltage, and then raised from the intermediate voltage to the voltage “VPGM+Vth”. In the third embodiment, when raising the voltage VRDEC from a voltage VCC to the voltage “VPGM+Vth (=VPGMH)”, the voltage VRDEC is first raised from the voltage VCC to a first voltage level, then raised from the first voltage level to a second voltage level, and finally raised from the second voltage level to the voltage “VPGM+Vth”.

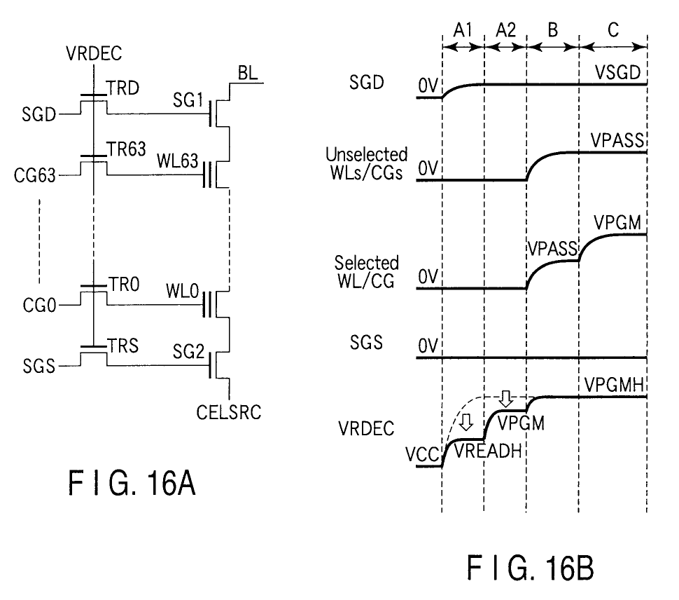

FIG. 16A is a circuit diagram showing the arrangements of transfer transistors and a NAND string according to the third embodiment of the present invention. FIG. 16B is a view showing voltage waveforms to be applied to transfer transistors TR0 to TR63, TRD, and TRS in the third embodiment.

As shown in FIG. 16B, in period Al before a voltage VPASS is applied, the voltage VRDEC is a voltage “VREAD+Vth (=VREADH)” (the first voltage level). The period A1 is a period during which a selection gate line SGD rises from 0 V to a voltage VSGD. Then, in period A2 before the voltage VPASS is applied and immediately after period A1, the voltage VRDEC is a voltage VPGM (the second voltage level). In period B during which the voltage VPASS is applied and period C during which the voltage VPGM is applied, the voltage VRDEC is the voltage “VPGM+Vth (=VPGMH)”. By thus controlling the voltage VRDEC to be applied to the gate of the transfer transistor, it is possible to reduce the stress voltage to be applied to the transfer transistor and the stress time.

In the third embodiment, when raising the voltage VRDEC from the voltage VCC to the voltage VPGMH in a write operation, the voltage VRDEC is first raised from the voltage VCC to the voltage VREADH and maintained at the voltage VREADH for a predetermined time, then raised from the voltage VREADH to the voltage VPGM and maintained at the voltage VPGM for a predetermined time, and finally raised from the voltage VPGM to the voltage VPGMH. That is, when raising the voltage VRDEC from the voltage VCC to the voltage VPGMH, the voltage VRDEC is first raised in two steps to the first voltage level and to the second voltage level higher than the first voltage level, and then raised to the voltage VPGMH. This makes it possible to reduce the voltage stress to be applied to the gate insulating film of the transfer transistor in a write operation.

Also, the output voltage of the voltage VRDEC can be controlled by using the same switching signals as shown in the row (b) of FIG. 7A and the row (b) of FIG. 13A, and the same control switching circuits as shown in FIGS. 7B and 13B. The rest of the arrangements and effects are the same as those of the first embodiment.

Note that each of the above embodiments is an example in which the voltage VRDEC is applied to the gate of the transfer transistor, and the voltages VPASS and VPGM are applied to the source-to-drain current path. In the transfer transistor HVPTr1 shown in FIG. 1C, however, 0 V is applied to the gate, and the voltage VRDEC is applied to the source-to-drain current path. Even in this case, the high-voltage stress is similarly applied to the gate insulating film. Therefore, the voltage stress to be applied to the gate insulating film of the transfer transistor can be reduced in the same manner as above by controlling the voltage VRDEC as explained in each embodiment.

Note also that each of the above-mentioned embodiments has been explained by taking the transfer of the write voltage to the transfer transistor in a write operation as an example. However, the present invention is not limited to this, and is similarly applicable to a transfer transistor to which a high voltage is transferred, such as when an erase voltage is applied to a transfer transistor in an erase operation.

Each embodiment of the present invention can provide a nonvolatile semiconductor memory device capable of reducing the voltage stress generated in a transfer transistor for transferring a high voltage to be used in, e.g., a write operation or erase operation.

Furthermore, the above-mentioned embodiments can be practiced singly and can also be practiced as they are appropriately combined. In addition, the above embodiments include inventions in various stages, so these inventions in the various stages can also be extracted by properly combining a plurality of constituent elements disclosed in the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
a memory cell group having a plurality of memory cells each including a floating gate and a control gate, the plurality of memory cells having current paths connected in series;
a first transfer transistor which transfers a write voltage to at least one memory cell in the memory cell group; and
a switching circuit which applies a voltage to a gate of the first transfer transistor,
wherein in a write operation, when a first voltage higher than a power supply voltage and lower than the write voltage is applied to the control gate of an unselected memory cell, the switching circuit applies an intermediate voltage higher than the first voltage and not more than the write voltage to the gate of the first transfer transistor.

2. The device according to claim 1, wherein the intermediate voltage is higher by a threshold voltage of the first transfer transistor than the first voltage.

3. The device according to claim 1, wherein the intermediate voltage is higher by a threshold voltage of the first transfer transistor than a second voltage to be applied to the control gate of the unselected memory cell in a read operation.

4. The device according to claim 1, wherein in the write operation, the switching circuit applies a threshold voltage of the first transfer transistor to the gate of the first transfer transistor immediately before the first voltage is applied to the control gate of the unselected memory cell.

5. The device according to claim 1, wherein in the write operation, the switching circuit applies the power supply voltage to the gate of the first transfer transistor immediately before the first voltage is applied to the control gate of the unselected memory cell.

6. The device according to claim 1, wherein in the write operation, the switching circuit applies a voltage higher by a threshold voltage of the first transfer transistor than the write voltage to the gate of the first transfer transistor, when the write voltage is applied to the control gate of a selected memory cell.

7. The device according to claim 1, wherein
the switching circuit includes a second transfer transistor connected to the gate of the first transfer transistor, and
in the write operation, the intermediate voltage is applied to a current path of the second transfer transistor when the first voltage is applied to the control gate of the unselected memory cell.

8. A nonvolatile semiconductor memory device comprising:
a memory cell group having a plurality of memory cells each including a floating gate and a control gate, the plurality of memory cells having current paths connected in series;
a first transfer transistor connected to the control gate of at least one memory cell in the memory cell group; and
a switching circuit which applies a voltage to a gate of the first transfer transistor,
wherein in a write operation, when a first voltage higher than a power supply voltage and lower than a write voltage is applied to the control gate of an unselected memory cell, the switching circuit applies an intermediate voltage higher than the first voltage and not more than the write voltage to the gate of the first transfer transistor.

9. The device according to claim 8, wherein the intermediate voltage is higher by a threshold voltage of the first transfer transistor than the first voltage.

10. The device according to claim 8, wherein the intermediate voltage is higher by a threshold voltage of the first transfer transistor than a second voltage to be applied to the control gate of the unselected memory cell in a read operation.

11. The device according to claim 8, wherein in the write operation, the switching circuit applies a threshold voltage of the first transfer transistor to the gate of the first transfer transistor immediately before the first voltage is applied to the control gate of the unselected memory cell.

12. The device according to claim 8, wherein in the write operation, the switching circuit applies the power supply voltage to the gate of the first transfer transistor immediately before the first voltage is applied to the control gate of the unselected memory cell.

13. The device according to claim 8, wherein in the write operation, the switching circuit applies a voltage higher by a threshold voltage of the first transfer transistor than the write voltage to the gate of the first transfer transistor, when the write voltage is applied to the control gate of a selected memory cell.

14. The device according to claim 8, wherein
the switching circuit includes a second transfer transistor connected to the gate of the first transfer transistor, and
in the write operation, the intermediate voltage is applied to a current path of the second transfer transistor when the first voltage is applied to the control gate of the unselected memory cell.

15. A nonvolatile semiconductor memory device comprising:
a memory cell group having a plurality of memory cells each including a floating gate and a control gate, the plurality of memory cells having current paths connected in series;
a first transfer transistor which transfers a write voltage to at least one memory cell in the memory cell group; and
a switching circuit which applies a voltage to a gate of the first transfer transistor,
wherein in a write operation, immediately before a first voltage higher than a power supply voltage and lower than the write voltage is applied to the control gate of an unselected memory cell, the switching circuit applies an intermediate voltage higher than the first voltage and not more than the write voltage to the gate of the first transfer transistor.

16. The device according to claim 15, wherein the intermediate voltage is higher by a threshold voltage of the first transfer transistor than a second voltage to be applied to the control gate of the unselected memory cell in a read operation.

17. The device according to claim 15, wherein the intermediate voltage is the write voltage.

18. The device according to claim 15, wherein the switching circuit applies the power supply voltage to the gate of the first transfer transistor before applying the intermediate voltage.

19. The device according to claim 15, wherein in the write operation, the switching circuit applies a voltage higher by a threshold voltage of the first transfer transistor than the write voltage to the gate of the first transfer transistor, when the write voltage is applied to the control gate of a selected memory cell.

20. The device according to claim 15, wherein the intermediate voltage is first raised to a third voltage higher than the power supply voltage and maintained at the third voltage for a predetermined period, and then raised to a fourth voltage higher than the third voltage and not more than the write voltage and maintained at the fourth voltage for a predetermined period.
